(19) United States
(12) Patent Application Publication
(10) Pub. No.: US 2016/0143173 A1
(43) Pub. Date: May 19, 2016

(54) Patch Bay Elysium

(71) Applicant: Archie Thompson, Carbondale, IL (US)

(72) Inventor: Archie Thompson, Carbondale, IL (US)

(21) Appl. No.: 14/538,480

(22) Filed: Nov. 11, 2014

(51) Int. Cl. H05K 7/02

(52) U.S. Cl. CPC H05K 7/026

(57) ABSTRACT

The present invention provides a patch bay with an input selector switch beneath each input of the front panel. The device provides convenience and routing flexibility when using a patch bay by including a multi-position input-select switch, knob or push button on front panel to choose the desired input. It can be used to insert any needed voices, effects or instruments on the front face of the invention next to its accompanying switch.

### CROSS REFERENCE TO RELATED APPLICATION

This application claims the benefit of U.S. Provisional Application No. 61908198 filed Nov. 25, 2013, which is hereby incorporated by reference in its entirety.

### BACKGROUND

Conventional patch bays require users to manually plug and unplug cables. This can result in improper insertion which can be time consuming and frustrating. This causes significant wear and tear on cables and equipment. Additionally, smaller patch bays typically do not provide musicians with many options to cover the desired band or instrument setup. Personal to medium sized studios usually do not have the resources to pre mic and/or have instruments ready to record at the flick of a switch. The present invention remedies that problem.

Devices are known in the prior art that relate to patch bays with multiple inputs. The most similar device located provides a patch bay that includes a front panel having multiple XLR/TRS combination jacks and a rear panel having multiple outputs. This device, however, does not disclose an input selector switch beneath each input on the front panel.

### SUMMARY

The present invention provides a patch bay with an input selector switch, knob or push button beneath each input of the front panel. The device provides convenience and routing flexibility when using a patch bay by including a multiple-position input-select switch or a pull button to choose the desired input. The device, therefore, eliminates the hassle associated with plugging and unplugging cables, saves a significant amount of time and frustration, and benefits music studio engineers and first-time recording enthusiasts.

### BRIEF DESCRIPTION OF DRAWINGS

FIG. 1 drawing illustrates how the back of the switch would look. This shows the user how this unit is wired and how the lead would go to the appropriate input/output jacks and shows how the common lead would be in an ideal position to place the capacitor to stop the popping sound you get when switching between live feeds.

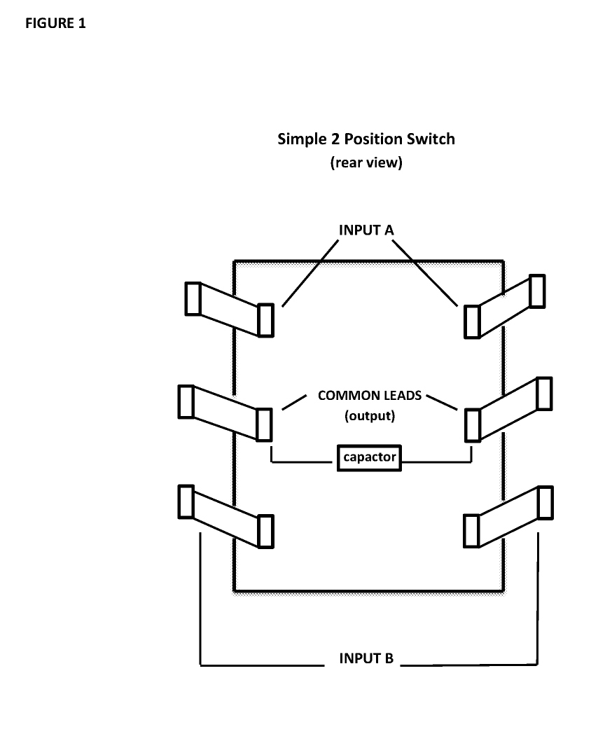

FIG. 2 illustrates the 6 Front Plate Inputs that shows how a half rack space unit would be set up for quarter inch input/output with paddle switch beneath each insert.

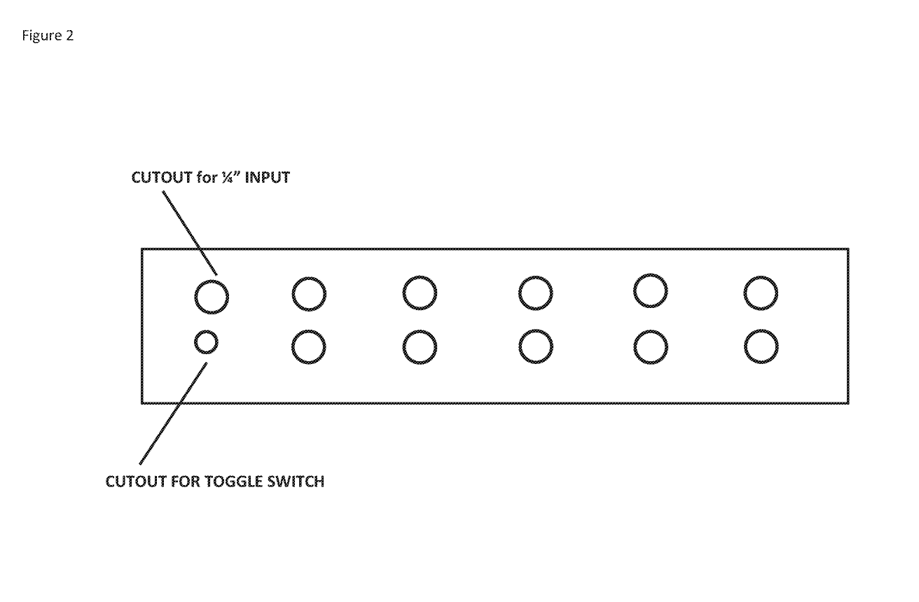

FIG. 3 (Combination XLR and Quarter Inch Half Rack Unit) drawing illustrates how different sized inputs can be placed in the same unit.

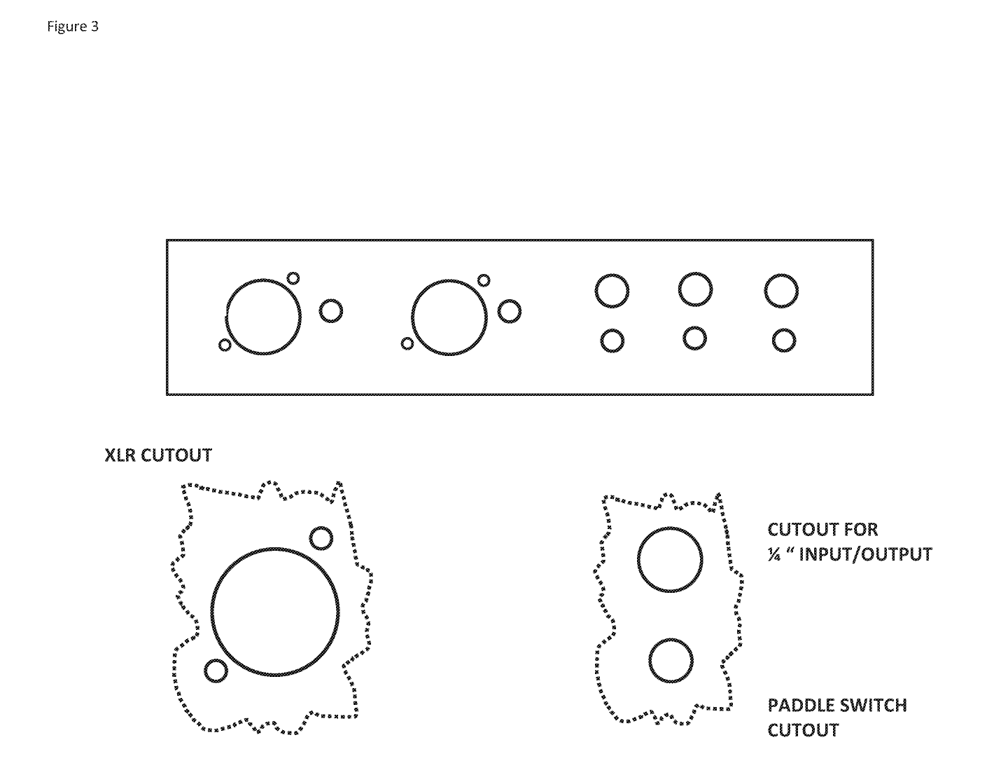

FIG. 4 drawing illustrates the back of the unit where you have six separate double inputs and one output beneath each input.

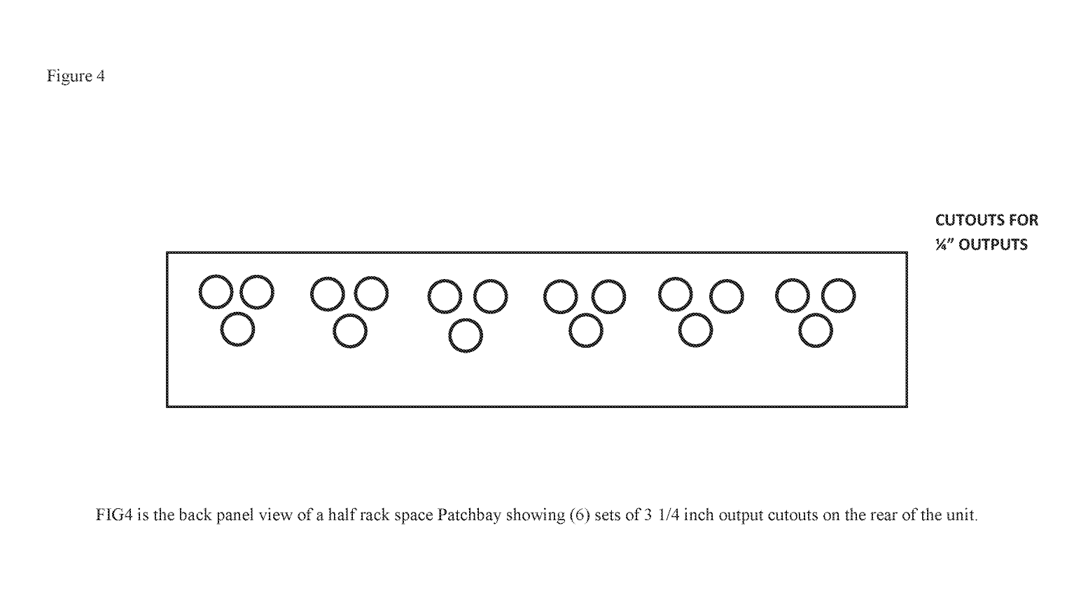

The features shown in the drawings are examples of the different types and sizes of the present invention. Note, the drawings are for illustration only and not intended by any means as a definition of the limits of the invention.

### DETAILED DESCRIPTION OF INVENTION

The Patch Bay Elysium is an invention brought about by necessity. It involves a switch, be it a toggle switch, rotary knob or push button to choose which input goes to the output. These switches appear on the front face of the unit along with XLR, RCA or quarter inch connection types.

The unit is flexible because it comes in different sizes from the small 500 series type rack space modules that the front face measures 5.25 inches×1.5 inches to the 3 rack space extra-large units that accept a large number of inputs and outputs. The most common size of these units are half rack units to customizable for the individual recording studio.

The wires are connected to the switches and input/output connection inserts using soldering techniques or different types of connection clips.

the popping noise that you get when switching a hot signal is handled by a 0.001 pF-150 pf capacitor attached at the leads of the switch, preferably a 20 pF capacitor is used.

Typically, three inputs to one output is what this unit uses, but four or five inputs to one output is easily accomplished.

These units fit into the usual type of rack space that is found in a recording studio.

The half space rack unit fits on several types of rack mounts that screw underneath in the center of these units. The smaller and larger units screw into their positions.

1. I claim this invention makes patch bay routing easier, faster and reduces wear and tear on equipment and connections by use of switches on the front panel along with an input for each switch on the front panel.

2. I claim this invention allows complete studio setups to be switched in or out without adjusting any wires.
